(19) United States
(12) Patent Application Publication
(10) Pub. No.: US 2006/0104035 A1
(43) Pub. Date: May 18, 2006

(54) Edge plated printed wiring boards

(76) Inventors: Kalu K. Vasoya, Placentia, CA (US); Bharat M. Mangrolia, Huntington Beach, CA (US); Don Roy, Huntington Beach, CA (US)

Correspondence Address: CHRISTIE, PARKER & HALE, LLP, PO BOX 7068, PASADENA, CA, 91109-7068, US

(21) Appl. No.: 11/211,942

(22) Filed: Aug. 24, 2005

Related U.S. Application Data
(60) Provisional application No. 60/604,242, filed on Aug. 24, 2004.

(51) Int. Cl. H05K 7/20

(52) U.S. Cl. 361/704

(57) ABSTRACT

Printed wiring board assemblies are described that include printed wiring boards having at least on thermally conductive plane. In addition, the printed wiring boards can also include edge plating on at least a portion of an edge of the printed wiring board. The printed wiring boards can also include heat spreaders, heat sinks and/or thermally conductive heat paths to dissipate heat from the printed wiring board assembly. In many instances, the heat spreaders include microfoils. In one embodiment, the invention includes at least one circuit layer, at least one dielectric layer, at least one thermally conductive plane and edge plating that contacts the at least one thermally conductive plane.

### CROSS-REFERENCE TO RELATED APPLICATION

This application claims the benefit of U.S. Provisional Patent Application No. 60/604,242, filed Aug. 24, 2004, the contents of which are expressly incorporated herein by reference in its entirety.

### BACKGROUND

The present invention generally relates to thermal management and more specifically relates to thermal management of printed wiring boards.

Activity of devices mounted on printed wiring boards can generate heat. Excessive heat can cause the devices mounted on the printed wiring board to fail. Failure of devices is particularly prevalent when “hot spots” develop on a printed wiring board. “Hot spots” typically arise when a number of devices are located in close proximity to each other. The difficulty devices have with dissipating heat tends to depend upon the proximity and number of adjacent devices. The greater the proximity and the larger the number of adjacent devices, the greater the likelihood that a “hot spot” will develop due to the inability of the device to adequately dissipate heat.

A number of strategies exist for increasing the dissipation of heat from electronic devices mounted on printed wiring boards. Options include air cooling, liquid cooling, heat sinks and heat exchangers to draw heat away from electronic devices. Thermally managed printed wiring boards such as those described in U.S. Pat. No. 6,869,664 to Vasoya et al. and U.S. patent application Ser. No. 11/131,130 the disclosure of which is incorporated herein by reference in its entirety, use thermally conductive planes within the printed wiring board to draw heat away from devices mounted on the surface of the printed wiring board. Conduction of heat away from the surface of the printed wiring board to thermally conductive planes can be increased using thermal vias or by increasing the thermal conductivity of the materials used in the construction of the printed wiring board.

### SUMMARY OF THE INVENTION

Embodiments of the present invention draw heat away from electronic devices mounted on the printed wiring board. In one aspect of the invention, edge plates are used to draw heat from thermal layers in the printed wiring boards. In another aspect of the invention edge plates and thermally conductive casings are used to conduct heat both directly away from electronic devices mounted on the printed wiring board and to conduct heat away from electronic devices mounted on the printed wiring board through the printed wiring board.

In one embodiment, the invention includes at least one circuit layer, at least one dielectric layer, at least one thermally conductive plane and edge plating that contacts the at least thermally conductive plane.

In a further embodiment, at least one of the thermally conductive planes is constructed from carbon fiber impregnated with resin, the carbon fiber is woven and the carbon fiber weave is balanced. Alternatively, the carbon fiber weave can be unbalanced. In many embodiments, the carbon fiber weave is a Plain weave, Twill weave, 2×2 twill, Basket weave, Leno weave, Satin weave, Stitched Uni Weave or 3D (Three dimensional) weave.

In an additional embodiment, the carbon fibers include PAN fibers. In another further In another further embodiment, the carbon fibers include Pitch fibers.

In another additional embodiment, the carbon fibers form a mat. In a further embodiment again, the carbon fiber is unidirectional.

In an additional embodiment again, the carbon fibers are spin broken. Alternatively, at least some of the fibers can be stretch broken.

In a yet further embodiment, the thermally conductive plane includes metal cladding.

In many embodiments, the at least one of the thermally conductive planes includes graphite, chemical vapor deposition (CVD) diamond, diamond, diamond like carbon (DLC), carbon composite, graphite composite or CVD composite.

In yet another embodiment, least one of the thermally conductive planes includes fibrous material coated in metal.

In many embodiments, the metal coated fibrous material includes Carbon, Graphite, E-glass, S-glass, Aramid, Kevlar or Quartz. In addition, the metal coating the fibrous material includes Nickel, Copper, Palladium, Silver, Tin or Gold.

In a still further embodiment, at least one of the thermally conductive planes includes a substrate impregnated with resin. In many instances, the resin is an Epoxy based resin. In several embodiments, the resin is a Phenolic based resin, a Bismaleimide Triazine epoxy (BT) based resin, a Cynate Ester based resin or Polyimide based resin.

In still another embodiment, the resin includes at least one filler to improve the thermal conductivity of the thermal plane. In many embodiments, the filler is Pyrolytic Carbon powder, Carbon powder, Carbon particles, Diamond powder, Boron Nitride, Aluminum Oxide, Ceramic particles or Phenolic particles.

In a still further embodiment again, at least one of the thermally conductive planes includes a Carbon plate.

In many embodiments, at least on of the thermally conductive planes includes Carbon-Silicon Carbide (C—SiC), a metal matrix composite, a metal or Boron Nitride.

In still another embodiment again, at least one of the thermally conductive planes possesses an in plane thermal conductivity of greater than 3 W/m.K. In addition, at least one of the thermally conductive planes can possess an in plane thermal conductivity is greater than 50 W/m.K. Moreover, at least one of the thermally conductive planes can possess an in plane thermal conductivity is greater than 300 W/m.K In another further embodiment, the invention includes a printed wiring board including at least one thermally conductive plane, an electronic device mounted on the printed wiring board and edge plating that contacts at least one of the thermally conductive planes.

Still another further embodiment also includes a heat spreader mounted to the printed wiring board and the edge plating contacts the heat spreader. The heat spreader can include microfins. In addition, the electronic device can also contact the heat spreader. Furthermore, the edge plating can be connected to the heat spreader via a thermal interface material and the electronic device can be connected to the heat spreader via a thermal interface material.

Yet another further embodiment also includes a heat sink that contacts the edge plating.

Another further embodiment again also includes a heat sink that is connected to the edge plating by at least thermal interface material.

Still yet another further embodiment includes a heat sink that is connected to the edge plating by at least a heat spreader.

Still yet another further embodiment again includes thermally conductive paths connected to the edge plating. In many embodiments, the thermally conductive paths include Copper and can be wires with one end of each wire connected to the edge plating or strips with one end of each strip connected to the edge plating.

Still yet another additional further embodiment also includes a second printed wiring board including a thermally conductive plane and edge plating and a heat sink. In addition, the edge plating of both the first and second printed wiring boards contact the heat sink.

Still yet another additional further embodiment again includes a second printed wiring board including a thermally conductive plane and edge plating and a heat sink. In addition, a heat spreader is mounted to each of the printed wiring boards and each of the edge platings of the printed wiring boards contacts the heat sink via the heat spreaders.

In a still yet further additional embodiment, the electronic devices are dies directly mounted on the printed wiring board.

In a still yet further additional embodiment again, the electronic devices are dies connected to the printed wiring board as at least one die stack.

An embodiment of the method of the invention includes, constructing a printed wiring board including at least one thermally conductive plane, prefabricating the edge of the printed wiring board in preparation for edge plating, plating thermally conductive edge plating onto the printed wiring board, finish the outer layers of the printed wiring board and mounting electronic devices on the printed wiring board.

A further embodiment of the method of the invention also includes adding thermal interface material to the edge plating.

Another embodiment of the method of the invention also includes mounting a heat spreader to the printed wiring board.

A still further embodiment of the method of the invention also includes connecting a heat sink to the heat spreader.

Still another embodiment of the method of the invention also includes forming microfins in the heat spreader.

A yet further embodiment of the method of the invention also includes connecting the edge plating to a heat sink.

Yet another embodiment of the method of the invention also includes forming microfins in the edge plating.

### BRIEF DESCRIPTION OF THE DRAWINGS

FIG. 1 is a schematic isotropic view of a printed wiring board assembly in accordance with one embodiment of the present invention including a casing that has been partially cut away to reveal electronic devices mounted on a printed wiring board;

FIG. 2 is a flow chart illustrating a process for manufacturing a printed wiring board assembly in accordance with the present invention;

FIG. 3 is a schematic cross-sectional view of a printed wiring board assembly similar to that shown in FIG. 1;

FIG. 4 is schematic cross-sectional view of the printed wiring board illustrated in FIG. 1;

FIG. 5 is a schematic cross-sectional view of multiple printed wiring boards connected to a common heat sink in accordance with an embodiment of the present invention;

FIG. 6 is a schematic cross-sectional view of multiple printed wiring board assemblies that include thermally conductive cases connected to a common heat sink in accordance with an embodiment of the present invention;

FIG. 7 is a schematic cross-sectional view of a printed wiring board assembly including electronic components mounted on the printed wiring board using die stacking in accordance with an embodiment of the present invention;

FIG. 8 is a schematic cross-sectional view of a printed wiring board assembly including a segmented thermally conductive casing in accordance with an embodiment of the present invention;

FIG. 9 is an schematic cross-sectional view of a printed wiring board assembly in accordance with the present invention that includes edge plating for dissipating heat;

FIG. 10 is a schematic isotropic view of a printed wiring board assembly including a thermally conductive casing having microfins in accordance with an embodiment of the present invention

FIG. 11 is a schematic isotropic view of a printed wiring board assembly including thermally conductive paths connected to the edge plating of a printed wiring board in accordance with an embodiment of the present invention.

### DETAILED DESCRIPTION OF THE INVENTION

Turning now to the drawings, printed wiring board assemblies including printed wiring boards having thermally conductive planes are illustrated. Electronic devices are connected to the printed wiring boards and at least a portion of one edge of the printed wiring boards include thermally conductive edge plating. Embodiments of printed wiring board assemblies in accordance with the present invention can use the thermally conductive edge plating to dissipate heat from the thermally conductive plane. In other embodiments, heat is further dissipated using heat spreaders such as thermally conductive casings and/or using heat sinks such as a microfin heat sink.

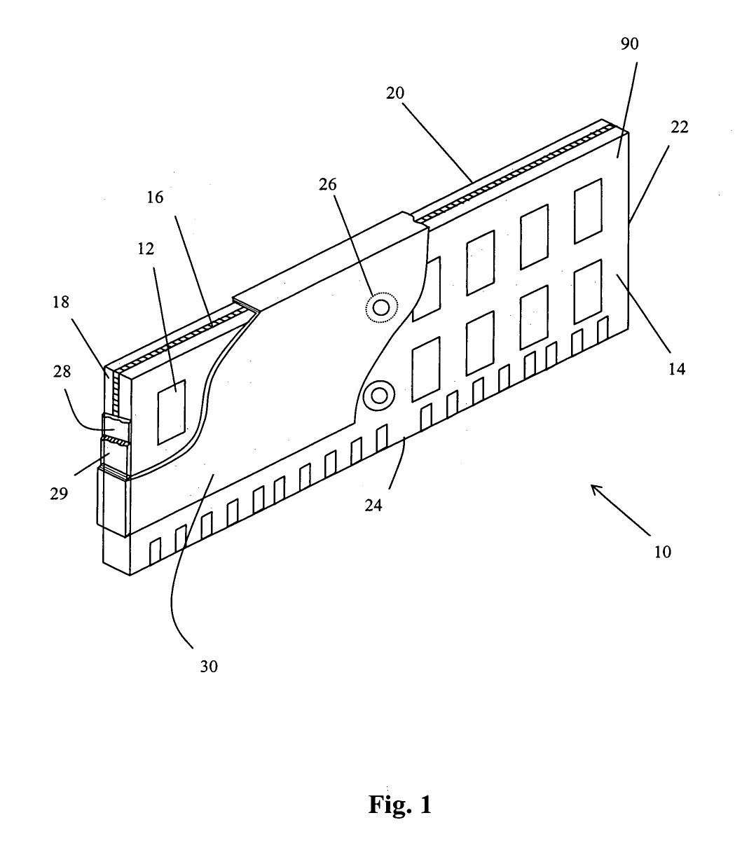

An embodiment of a printed wiring board assembly in accordance with the present invention is shown in a schematic fashion in FIG. 1. The printed wiring board assembly 10 includes a plurality of electronic devices 12 mounted on a thermally conductive printed wiring board 14. The printed wiring board has at least one thermally conductive plane 16, which extends to at least one of the edges of the printed wiring board 18, 20, 22 and 24. In several embodiments the thermally conductive plane also is intersected by mounting holes 26. In the illustrated embodiment, the edges of the printed wiring board 18 and 20 are plated with a thermally conductive edge plating 28. A thermal interface 29 is located between the edge plating and a thermally conductive casing 30.

In operation, the devices 12 mounted on the printed wiring board 14 generate heat. Some of the heat generated by the devices can dissipate via conduction through the printed wiring board to the nearest thermally conductive plane 16 and the relatively high thermal conductivity of the thermally conductive plane can cause heat to dissipate rapidly throughout the plane. At the edges of the thermally conductive plane, the edge plating 28 and thermal interface material 29 enable heat to conduct from the plane to the thermally conductive casing 30. Consequently, a heat flow path can be created from the devices through the board to the thermally conductive planes and from the thermally conductive planes to the thermally conductive casing via the edge plating.

The surface area of the thermally conductive casing can be significantly greater than that of the electronic devices and, therefore, can dissipate heat more rapidly. For embodiments where a heat generating device 12 contacts the thermally conductive casing 30, additional heat can conduct directly from the device to the thermally conductive casing.

Use of edge plating 28 can increase the rate at which heat conducts from the thermally conductive plane 16 to the thermally conductive casing 30. The edge plating can be a material having an extremely high thermal conductivity, which effectively increases the surface area with which the thermally conductive plane contacts the thermally conductive casing. In addition to increasing the ability of heat to dissipate from thermally conductive planes, the edge plating can increase the overall stiffness of the printed wiring board and in particular increase stiffness normal to the thickness of the plating.

The thermally conductive plane 16 is typically constructed from a material having a relatively high thermal conductivity. In one embodiment, the thermally conductive plane is a layer of carbon fiber impregnated with a thermally conductive resin similar to the resin impregnated carbon fiber substrates described in U.S. Pat. No. 6,869,664 to Vasoya et al. In addition to the resin impregnated carbon fiber, any of the materials described in U.S. Pat. No. 6,869,664 to Vasoya et al. for the construction of an electrically conductive constraining core can also be used in the construction of a thermally conductive plane in accordance with the present invention. In embodiments where the thermally conductive plane is also electrically conductive, processes in accordance with embodiments of the method of the present invention that can be used to ensure that the edge plating does not cause short circuits between circuits on different layers of the printed wiring board. These processes are discussed in detail below.

As can be appreciated, thermally conductive planes can be constructed from a wide variety of materials in addition to those indicated above. Examples of other suitable materials are now discussed. In many embodiments, the thermally conductive plane 16 can be constructed using any form of carbon including graphite, chemical vapor deposition (CVD) diamond, such as the CVD manufactured by Morgan Advanced Ceramics, Diamonex products division located at Allentown, Pa., diamond, diamond like carbon (DLC), carbon composite, graphite composite, CVD composite In many instances, carbon used in the construction of a thermally conductive plane 16 can take the form of a fibrous material that is impregnated with resin.

Examples of suitable fibers include part numbers CNG-90, CN-80, CN-60, CN-50, YS-90, YS-80, YS-60 and YS-50 manufactured by Nippon Graphite Fiber of Japan, K63B12, K13C2U, K13C1U, K13D2U, K13A1L manufactured by Mitsubishi Chemical Inc. of Japan or T300-3k, T300-1k, EWC-600X manufactured by Cytec Carbon Fibers LLC of Greenville, S.C. In other embodiments, thermally conductive planes can be constructed from PAN, Pitch or a combination of both fibers.

Carbon or other types of fibrous material coated in metal and impregnated with resin can be used in the construction of a thermally conductive plane 16 in accordance with embodiments of the present invention. Examples of fibers that can be coated with metal include Carbon, Graphite, E-glass, S-glass, Aramid, Kevlar, Quartz or any combination of these fibers. Examples of metals that are typically used to coat fibers include Nickel, Copper, Palladium, Silver, Tin and Gold. The services of manufacturers such as Electro Fiber Technologies located in Stratford, Conn. can be used to metal coat fibers.

When fibrous materials are used in the construction of a thermally conductive plane 16, the configurations in which the fibrous materials can be arranged can influence the mechanical and thermal properties of the printed wiring board 14. The fiber configurations can include being woven, unidirectional or non-woven mats. In several embodiments, the woven material can be in the form of a Plain weave, Twill weave, 2×2 twill, Basket weave, Leno weave, Satin weave, Stitched Uni Weave or 3D (Three dimensional) weave. Typically, heat is able to conduct more rapidly along the thermally conductive fibers than between the fibers. Therefore, the type of weave used can influence the direction of heat flow within a thermally conductive plane 16. In embodiments with a balanced weave, heat will tend to conduct away from a single heat source along the fibers evenly in four generally perpendicular directions. When an unbalanced weave is used the heat will not conduct evenly in all directions. More heat will conduct in the direction of the weave that includes a greater density of fibers than in the other direction of the weave. Therefore, an unbalanced weave can be used to control the direction in which heat flows. For example, an unbalanced weave can be used to increase heat flow to the edges of the printed wiring board closest to the heat source. In addition, an unbalanced weave can be used to direct heat flow away from adjacent heat sources and avoid the creation of “hot spots” within the thermally conductive plane.

As indicated above, fibers can be used to form non-woven material. Examples of non-woven materials that can be used in the construction of a thermally conductive plane in accordance with an embodiment of the invention include fibers in the form of Uni-tape or a mat. In many embodiments, Carbon mats such as a grade number 8000040 2 oz mat or a 8000047 3 oz mat manufactured by Advanced Fiber NonWovens of East Walpole, Mass. can be used in the construction of thermally conductive planes.

Fibers used in the construction of a thermally conductive plane in accordance with an embodiment of the invention can be continuous or discontinuous. In embodiments where discontinuous fibers are used, the fibers can be spin broken or stretch broken fibers such as part no. X0219 manufactured by Toho Carbon Fibers Inc. of Rockwood, Tenn.

In many embodiments, the resin used to construct the thermally conductive plane 16 is an Epoxy based resin such as EP387 or EP450 manufactured by Lewcott Corporation, Mass. In other embodiment, a thermally conductive plane can be constructed using resins such as Phenolic based resin, Bismaleimide Triazine epoxy (BT) based resin, Cynate Ester based resin and/or Polyimide based resin. Many resins used in accordance with embodiments of the present invention include fillers such as Pyrolytic Carbon powder, Carbon powder, Carbon particles, Diamond powder, Boron Nitride, Aluminum Oxide, Ceramic particles, and Phenolic particles to improve the thermal and/or physical properties of the thermally conductive planes 16. In several embodiments, resins can also increase the electrical conductivity of the thermally conductive plane 16.

A thermally conductive plane 16 can also be constructed in accordance with an aspect of the present invention using a Carbon plate, which can be made using compressed Carbon powder. In other embodiments, a suitable Carbon plate can be constructed using Carbon flakes or chopped Carbon fiber. In other embodiments, the thermally conductive plane 16 can be constructed from other types of materials such as C—SiC (Carbon-Silicon Carbide) manufactured by Starfire Systems Inc. of Malta, N.Y., metal matrix composites, metal, Boron Nitride and any combinations of above listed materials.

In many instances, the thermal conductivity of a thermally conductive plane is increased by cladding a substrate on one or both sides with a layer of metal such as copper.

In many instances of the invention, the thermally conductive plane is constructed from materials that, when unclad, have an in plane thermal conductivity of greater than 3 W/m.K. In many embodiments the in plane thermal conductivity is greater than 50 W/m.K. Often the in plane thermal conductivity can be in excess of 300 W/m.K. The choice of a material for use in the construction of the thermally conductive planes typically depends on the heat transfer, coefficient of thermal expansion and stiffness desired from the completed printed wiring board.

As will be discussed below, any of the materials that can be used in the construction of a printed wiring board (including the materials described in U.S. Pat. 6,869,664 to Vasoya et al. and U.S. patent application Ser. No. 11/131,130) can be used in the construction of the remainder of a printed wiring board including thermally conductive planes in accordance with various embodiments of the present invention.

In many embodiments, use of thermally conductive planes in printed wiring boards can result in a printed wiring board in accordance with the present invention having a thermal conductivity greater than 3.0 W/m.K in the plane of the printed wiring board and greater than 1.0 W/m.K through the thickness of the plane. In several embodiments, the thermal conductivity is greater than 5.0 W/m.K in-plane and greater than 1.5 W/m.K through the thickness of the plane. Other embodiments possess thermal conductivity greater than 10.0 W/m.K in-plane and greater than 2.0 W/m.K through the thickness of the plane.

As can be understood from the types of materials described above, the thermal plane 16 can possess the property of electrical conductivity. In embodiments where the thermally conductive plane is electrically conductive, the thermally conductive plane can be used as a functional layer.

A functional layer is a layer within a printed wiring board that contains circuits and/or regions that act as reference planes. Functional layers include ground planes, power planes and split plane layers. Non-functional layers are layers that are not part of the circuit of the printed wiring board. So-called non-functional layers are typically structural and are used to electrically isolate the functional layers of the printed wiring board and assist in defining the mechanical characteristics of the printed wiring board.

As discussed above, the edge plating facilitates the transfer of heat from a thermally conductive plane to a thermally conductive casing 30. Embodiments discussed in greater detail below demonstrate how edge plating can also be used to facilitate heat transfer from the thermally conductive plane to one or more heat sinks or to the ambient environment. In one embodiment, the edge plating is constructed from Copper. In other embodiments, edge plating can be constructed using Copper alloys, Silver, Palladium, Aluminum, Aluminum alloys, Germanium, Gold, Nickel, Ni-Au and Cu-Ni-Au. Typically, the edge plating is constructed from any material having a relatively high thermal conductivity. In many embodiments, the edge plating has a thermal conductivity greater than 2.0 W/m.K. In other embodiments, the thermal conductivity can be greater than 10.0 W/m.K and can be greater than 100.0 W/m.K.

Heat transfer between a thermally conductive plane 16 and a thermally conductive casing 30 or heat sink can be increased using a thermal interface material 29. The thermal interface 29 can reduce thermal resistance between the thermally conductive edge plating 28 and the thermally conductive case 30. In one embodiment, the thermal interface material 29 can be thermal grease, thermal adhesive, thermal tape, phase change material such as PCM45 manufactured by Honeywell Electronic Materials of Sunnyvale, Calif., dispensable gel such as TM150/350 manufactured by Honeywell Electronic Materials, solders or thermal pads such as GELVET manufactured by Honeywell Electronic Materials. Thermal interface material 29 can be dispensed during assembly, can be applied and then heat cured, applied like tape or can be pre-applied in solid state and then undergo a solid to liquid phase change at an elevated temperature to conform to adjacent surfaces and reduce thermal resistance. In another embodiment RNT foil technology manufactured by Reactive Nano Technologies Inc of Hunt Valley, Md., or highly thermally and electrically conductive Z-axis adhesive film such as ATTA LM-2, ATTA TF-1, IOB-3 ACF, TP-1 ACF manufactured by Btech Corp. of Longmont, Colo. can be used as the thermal interface material. In other embodiments, the thermal interface material can be implemented using a number of thermally conductive materials including vertically aligned Carbon/Graphite fiber composite tape, vertically aligned metal fiber/metal coated fiber film, Silver Oxide, Aluminum Oxide, Pyrolytic Carbon. In other embodiments other materials can be used to implement the thermal interface material having thermal conductivities greater than 1.0 W/m.K.

One of ordinary skill in the art would appreciate that any number of electronic devices can be mounted on a printed circuit board using a variety of techniques. Such devices can include memory chips, microprocessors, application specific integrated circuits (ASIC) and discrete devices. In one embodiment, the electronic devices are assembled onto the printed wiring board by component leads connected via a wave solder process. In other embodiments, electronic devices 12 can be attached to the printed wiring board 14 that are packaged as Thin Small Outline Packages (TSOP), Ball Grid Arrays (BGA), Ceramic Ball Grid Arrays (CBGA), Ceramic Column Grid Arrays (CCGA), Chip Scale Packages (CSP), Flip Chips, Flip Chip BGAs, Multi Chip Modules (MCM), System in Packages (SIP), System On Packages (SOP), Land Grid Arrays (LGA), Land Grid Area Arrays (LGAA), Wafer Level Packages (WLP) or that are simply attached using Direct Die Attach (DDA). In other embodiments, electronic devices can be assembled onto the printed wiring board by wire bonding or any other process that can be used to attach an electronic device to a printed wiring board.

A thermally conductive casing in accordance with an embodiment of the present invention can be constructed from any material capable of providing suitable structural and thermal properties. A thermally conductive casing is a type of device commonly referred to as a heat spreader. In one embodiment, the thermally conductive case is assembled over the printed wiring board and the electronic devices using rivets or bolts. The rivets or bolts can be secured to the printed wiring board through mounting holes. In addition, various types of clamps could be used. The attachment of thermally conductive casings is discussed further below. As will be discussed further below, the thermally conductive casing can be connected to heat sinks, can have fins and/or microfins to increase the rate at which heat can be dissipated.

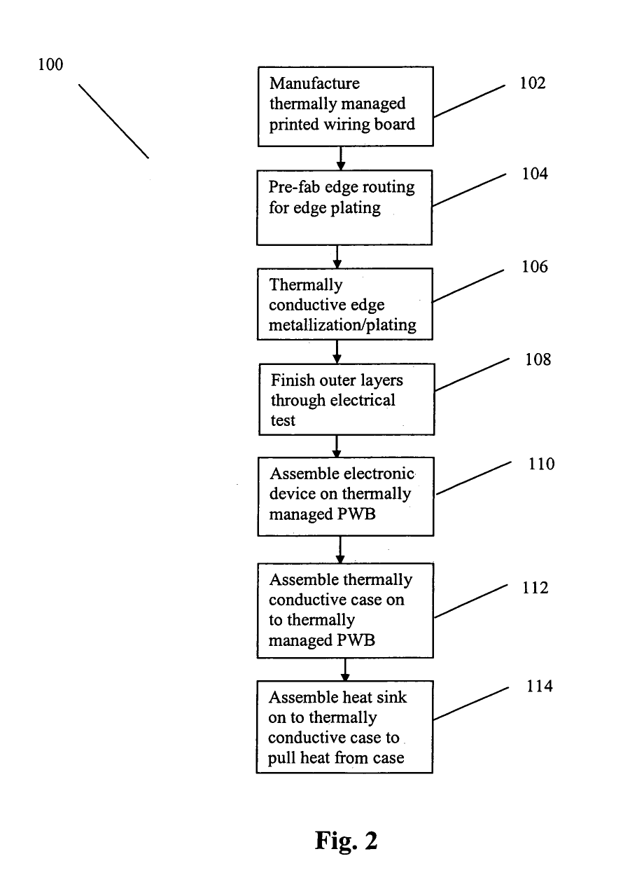

Printed wiring board assemblies in accordance with the present invention can be constructed in accordance with a process shown in FIG. 2. The process 100, includes manufacturing (102) a thermally managed printed wiring board including thermally conductive planes. Prefabricating (104) the edge for the edge plating. Thermally conductive edge plating is plated (106) onto the printed wiring board and the outer layers of the printed wiring board are finished (108). The electronic devices are mounted (110) onto the printed wiring board and a thermally conductive case is assembled (112) over the printed wiring board and electronic devices. As an additional step, a heat sink may then be attached 114 to the thermally conductive case.

In one embodiment, the printed wiring board 14 is constructed in accordance with the methods described in U.S. Pat. No. 6,869,664 to Vasoya et al. and U.S. patent application Ser. No. 11/131,130 as incorporated above by reference. In other embodiments, other printed wiring board structures including thermally conductive layers can be manufactured in accordance with techniques that are well known in the art. Typically, the circuits on the functional layers do not extend to the edges of the PWB to prevent the edge plating from creating short circuits. Although in embodiments where the thermal planes are also functional layers, the thermal planes can be connected by the edge plating provided short circuits can be tolerated. For example, when both thermal planes are also common ground planes.

In one embodiment, edge routing is performed using a carbide high speed routing tool used by a CNC routing machine manufactured by Excellon Automation of Torrance, Calif. The edge routing can be performed prior to a metallization process designed to establish electrical and or thermal connections between different electrical and or thermal plane layers. The edge routing followed by edge plating can prepare edges of a printed wiring board for the creation of a thermal connection between thermally conductive planes in the printed wiring board and a thermally conductive case.

In one embodiment, edge plating is performed using a conventional copper plating process. These processes typically require that printed wiring board panels be run through permanganate desmear baths or through a plasma etch back process to clean holes or slot walls prior to metal deposition. A thin layer of metal can be deposited on the walls of holes and slots by passing the panels through an electro-less Copper bath or by any equivalent process. The metal plating can then be completed by plating the required amount of metal over the thin deposit layer. A pulse plating process can also be used.

In one embodiment, finishing of the outer layers of the printed wiring board includes patterning circuits onto the outer layers of the printed circuit board, inspecting the outer layers, applying a solder mask, performing a surface finish process, final fabrication, electrical testing and performing a final inspection. In other embodiments, other processes can be performed that create a finished printed wiring board.

In several embodiments, heat sinks are attached to the thermally conductive cases to increase the ability of the printed wiring board assembly to dissipate heat into the environment. In several embodiments, a heat sink such as a finned heat sink made out of metal, metal alloys, Carbon, Graphite, Carbon composite or graphite composite can be used. In other embodiments, other types of heat sinks can be used. Examples of embodiments including heat sinks are discussed further below.

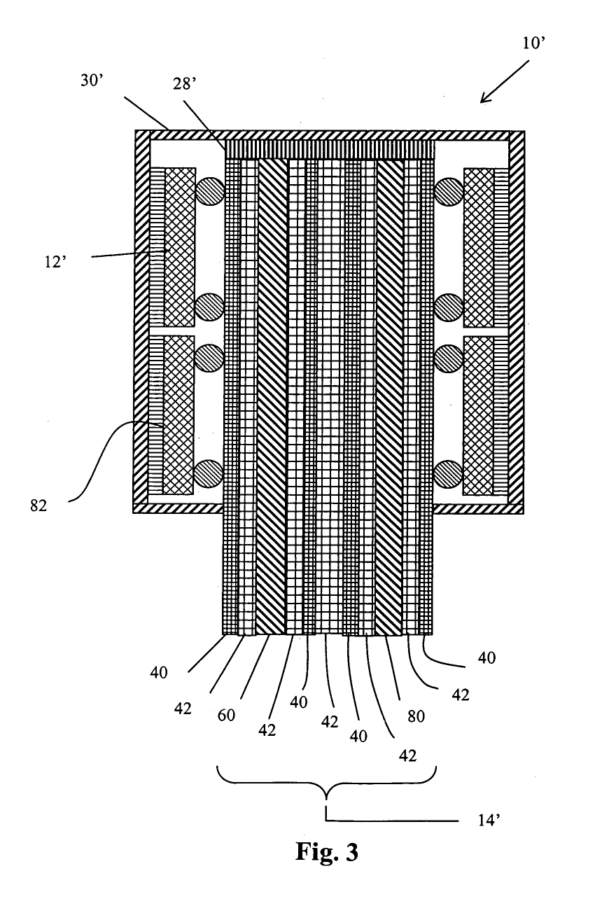

The printed wiring board assembly 10 shown in FIG. 1 includes a printed wiring board 14 with a single thermally conductive plane 16. In other embodiments, the printed wiring board used in the printed wiring board assembly can include multiple thermally conductive planes. A cross section of such a printed wiring board assembly 10′ in accordance with an embodiment of the present invention is illustrated in FIG. 3. The printed wiring board assembly is similar to the printed wiring board assembly shown in FIG. 1 in most respects except that the printed wiring board 14′ includes multiple thermally conductive planes and a thermal interface is not used between the edge plating and the thermally conductive case.

The printed wiring board 14′ includes a plurality of functional layers 40 that are separated by a plurality of dielectric layers 42. The printed wiring board 14′ also includes two thermally conductive planes 60 and 80. In one embodiment, a thermally conductive plane can be one of the functional layers in the printed wiring board. In other embodiments, the thermally conductive planes can be non-functional layers.

In one embodiment, thermally conductive planes are positioned close to the main surfaces of the printed wiring board to increase the rate at which heat flows from the surface of the printed wiring board to the thermally conducting planes. In other embodiments, the thermally conductive planes occupy a variety of locations within the layers of the printed wiring board.

The edge plating 28′ enables the transfer of heat between the thermally conductive planes 60 and 80 and a thermally conductive casing 30′. In other embodiments, the thermally conductive casing can directly contact the thermally conductive planes. In these embodiments, the thermally conductive casing essentially includes the edge plating.

In operation, printed wiring board assemblies in accordance with the present invention can transfer heat generated by electronic devices 12′ mounted on the printed wiring board to the thermally conductive case 30′. Heat can flow from the electronic devices to the thermally conductive planes 60 or 80 and from the thermally conductive planes to the thermally conductive casing via the edge plating layer 28′. Heat can also flow from an electronic device to the casing via direct contact between the electronic device and the thermally conductive case or via conduction through a thermal interface 82. Examples of thermal interface materials are discussed above.

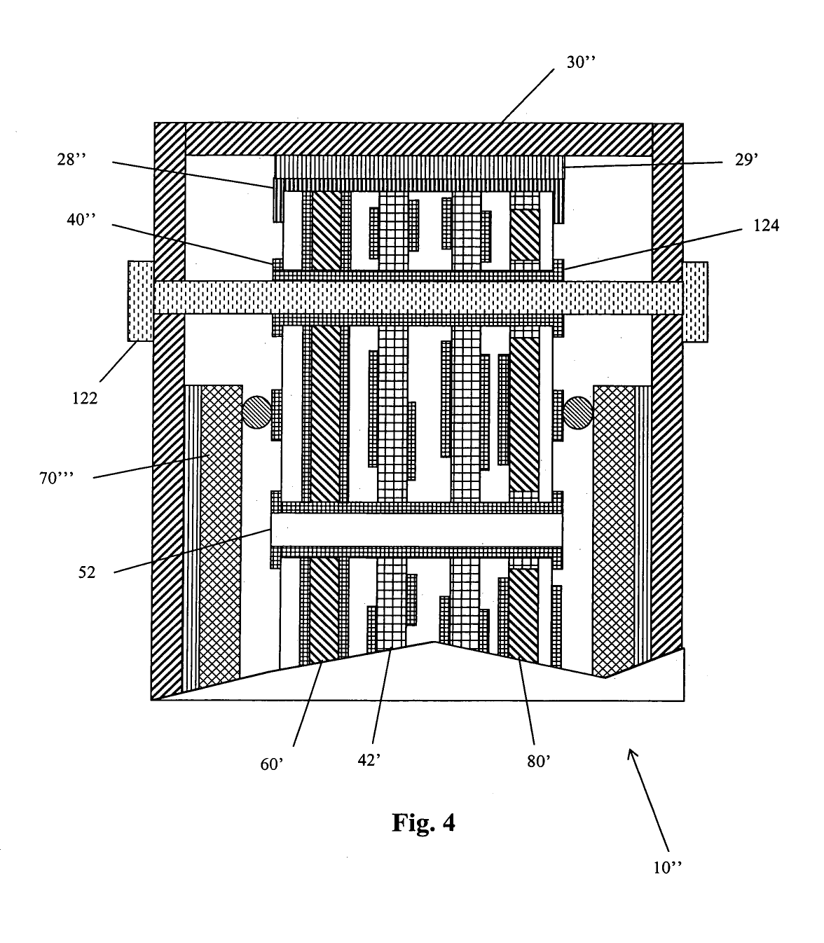

A thermally conductive casing can be mounted to a printed wiring board in a variety of ways. A printed wiring board assembly 10″in accordance with the present invention including a thermally conductive case 30′ mounted using a case mounting device 122 is illustrated in FIG. 4. The printed wiring board assembly also includes a thermal interface material 29′ located between the thermally conductive edge plating 28″ and the thermally conductive case 30″.

In the illustrated embodiment, a thermal path exists between the thermally conductive planes 60′ and 80′ and the thermally conductive case 30″ via the case mounting device 122. Heat transfer between the thermally conductive plane and the case mounting device 122 is facilitated by using a thermally conductive lining inside the mounting hole 124 that contains the case mounting device.

In one embodiment, the case mounting device is a screw constructed from Aluminum. In other embodiments, the case mounting device could be a pin, rod, rivet or any other device capable of securing a case to a printed wiring board when positioned within a mounting hole in the printed wiring board. Materials that can be used to construct case mounting devices in accordance with the present invention include Brass, Aluminum alloys, Copper, Copper alloys, other metal and metal alloys, Carbon composite, Graphite composite or any other material capable of a thermal conductivity greater than 10.0 W/m.K.

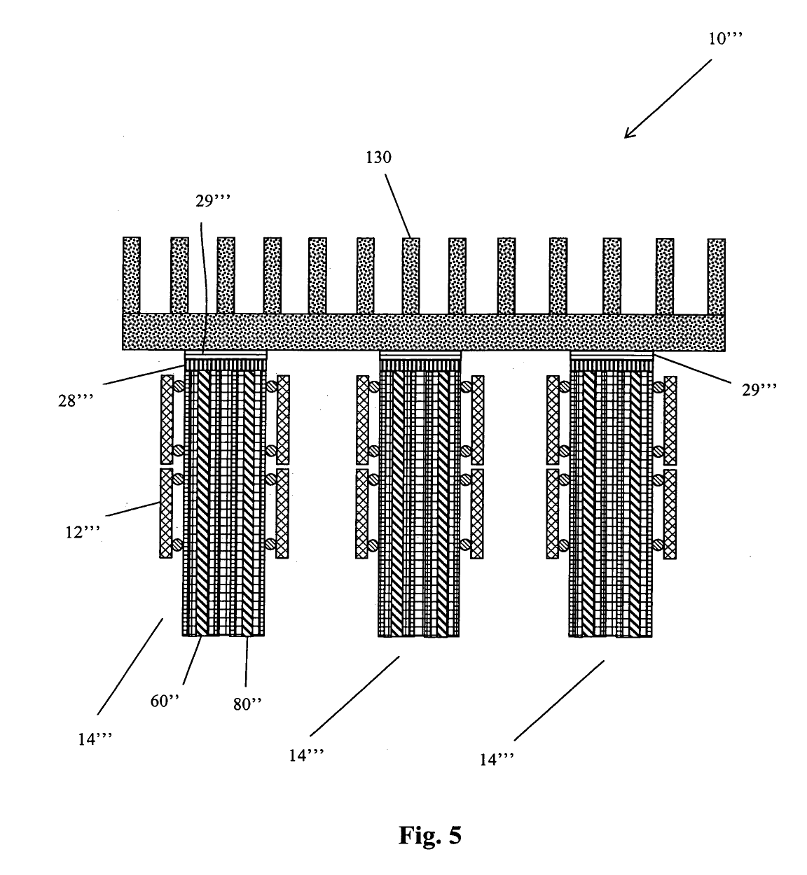

An embodiment of a printed wiring board assembly in accordance with the present invention that includes a number of printed wiring boards connected to a heat sink is illustrated in FIG. 5. The printed wiring board assembly 10′″ includes a plurality of printed wiring boards 14′″ on which electronic devices 12′″ are mounted. The printed wiring boards also include thermally conductive edge plating 28′−. Thermal interfaces 29′″ are used to transfer heat from the thermally conductive edge plating on each of the printed wiring boards to a heat sink 130.

Thermally conductive planes in the printed wiring board 60″ and 80″ can transfer heat generated by electronic devices mounted on the printed wiring boards to the heat sink via the thermally conductive edge plating 28′″ and thermal interface material 29′″. Both the thermal interface material and the thermally conductive edge plating can be constructed in the manner described above.

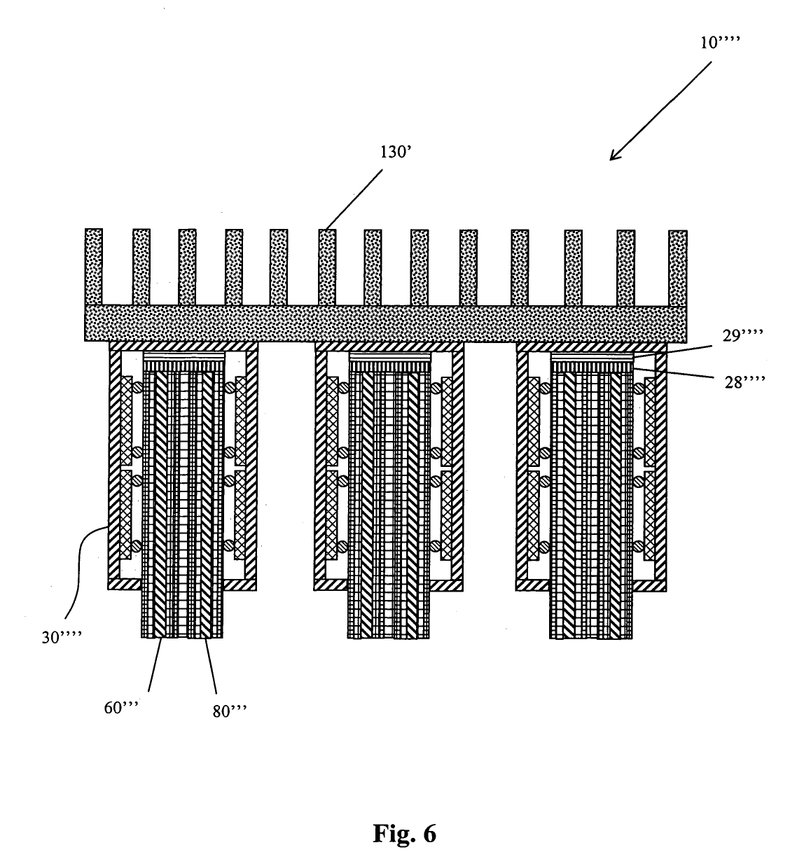

An embodiment of a printed wiring board assembly including multiple printed wiring boards possessing thermally conductive casings that are connected to a heat sink is illustrated in FIG. 6. The printed wiring board assembly 10″″ is similar to the printed wiring board assembly 10′″ illustrated in FIG. 5, except that each of the printed wiring boards are surrounded by a thermally conductive casing 30″″. In the embodiment illustrated in FIG. 6, heat can be drawn away from electronic devices through thermally conductive planes 60′″ and 80′″ in the printed wiring boards and through the thermally conductive casings 30″″. The presence of the heat sink 130′ can enable more rapid dissipation of heat from the thermal planes 60′″ and 80′″ and thermally conductive casings 30″″.

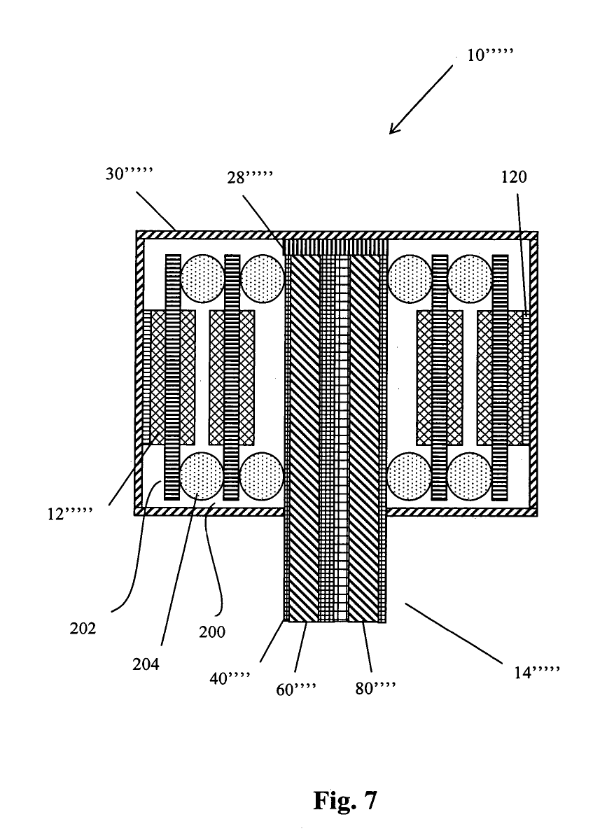

A printed wiring board assembly including stacked electronic devices in accordance with an embodiment of the present invention is illustrated in FIG. 7. The printed wiring board assembly 10′″″ uses a printed wiring board 14′″″ that includes thermally conductive planes 60″″, 80″″ and at least one thermally conductive edge plating 28′″″. Stacks of electronic devices 200 are attached to the printed wiring board and the stacks are enclosed in a thermally conductive case 30′″″. The thermally conductive case can contact the thermally conductive edge plating and the outermost electronic devices in the stacks. Various techniques can be used in the construction of stacks including those techniques described in U.S. patent application Ser. No. 10/930,397 the disclosure of which is incorporated herein by reference in its entirety.

Thermally conductive casings are a type of heat spreader. In the embodiments discussed above that include thermally conductive casings, the thermally conductive casings have tended to be continuous structures surrounding portions of a printed wiring board. In other embodiments, the thermally conductive casing can be segmented to optimize the efficiency of different thermal pathways. In embodiments where heat can dissipate through a number of pathways, segmentation can avoid one of the pathways dissipating heat back into the printed wiring board assembly through another less efficient thermal pathway.

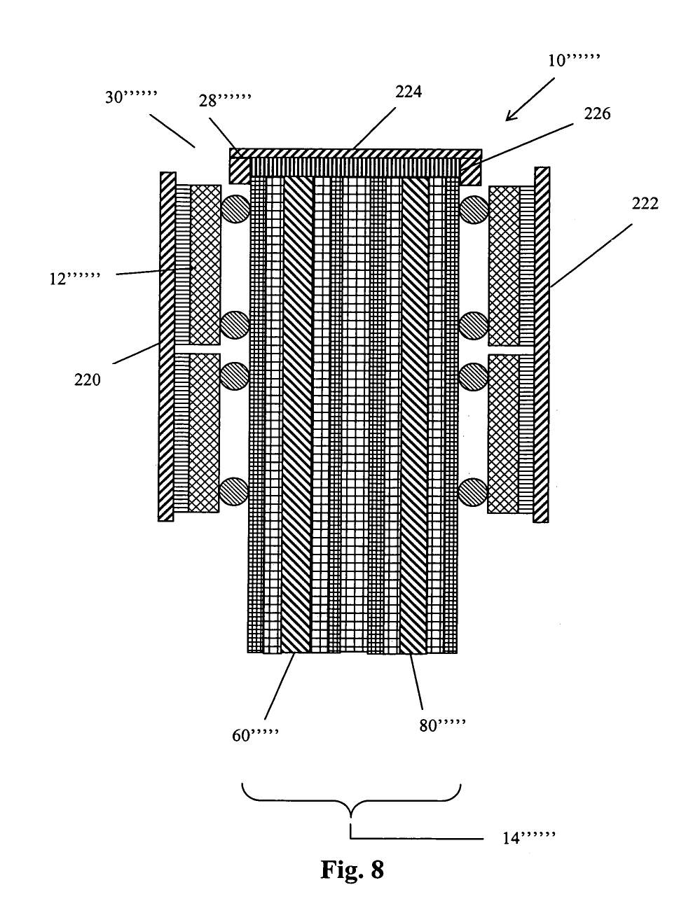

An embodiment of a printed wiring board assembly including a segmented thermally conductive casing is shown in FIG. 8. The thermally conductive casing 30″″″ is segmented into three pieces 220, 222 and 224. A first piece 220 of the thermally conductive casing contacts devices 12″″″ mounted on one side of the printed wiring board 14′″″″. A second piece 222 of the thermally conductive casing contacts devices 12″″″ mounted on the other side of the printed wiring board 14″″″. The third piece 224 of the thermally conductive plating contacts the edge plating 28″″″ of the printed wiring board via a thermal interface material 29′″″. Each of the pieces of the thermally conductive casing acts as a heat spreader. The first piece 220 spreads heat from a first group of the devices 12″″″, the second piece 222 spreads heat from a second group of the devices 12′″″ and the third piece 224 spreads heat from the thermal planes 60′″″ and 80′″″. The first and second pieces of the thermally conductive casing are mounted using mounting hardware (see discussion above). In other embodiments, the first and second pieces can also be mounted using sticky thermal tape. The third piece 224 includes a slot 226 that engages the edge of the printed wiring board 14′″″. In other embodiments, mounting hardware and/or sticky thermal tape can also be used in the mounting of the third piece of the thermally conductive casing.

Although the embodiment illustrated in FIG. 8 includes a thermally conductive casing segmented into three pieces, in other embodiments the casing can be segmented in any variety of ways. In several embodiments the casing is continuous, however, sections of material with low thermal conductivity are used to isolate regions of the thermally conductive casing from each other. Numerous embodiments include segmented thermally conductive casings that are connected in a manner or that include slots and/or holes that restrict heat flow between different regions of the thermally conductive casings.

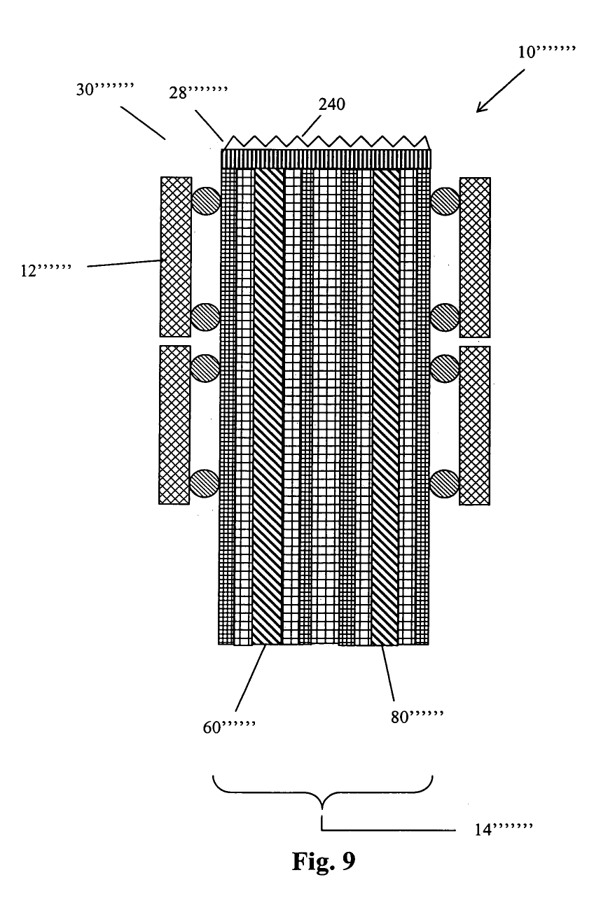

In other embodiments, the edge plating is not connected to a heat spreader. In these embodiments, the edge plating itself forms a heat spreader to dissipate heat into the ambient environment. A printed wiring board that includes edge plating configured to dissipate heat to the ambient environment is illustrated in FIG. 9. The edge plating 28′″″″ includes ridges 240 to increase its surface area. Increased surface area can increase the rate at which heat dissipates. In other embodiments, other techniques for increasing the surface area of the edge plating can be used.

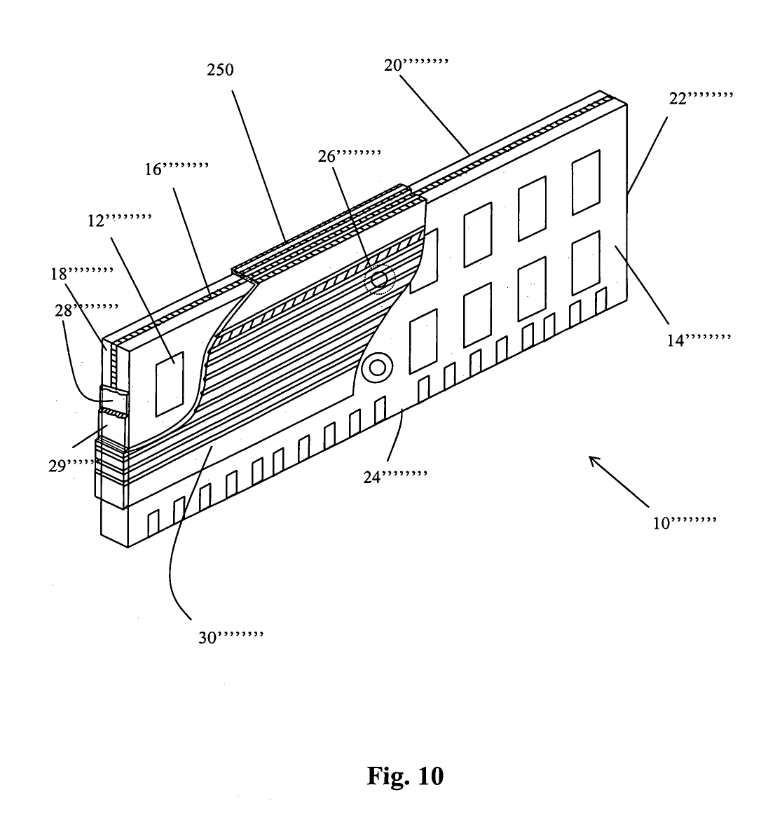

Increasing surface area can increase heat dissipation from heat spreaders such as thermally conductive casings. A printed wiring board assembly including a heat spreader having microfins is shown in FIG. 10. The printed wiring board assembly 10″″″″ is similar to the printed wiring board assembly 10′ shown in FIG. 3 with the exception that the thermally conductive casing 30″″″″ includes microfins 250. The microfins 250 extend from the thermally conductive casing 30″″″″. In one embodiment, microfins 250 can be manufactured using Micro-Deformation Technology. In other embodiments, microfins can be formed separately and attached to the thermally conductive casing 30″″″″ using a thermally conductive adhesive such as an adhesive tape or using a thermal interface material. In other embodiments, techniques for attaching microfings to a thermally conductive casing include soldering, welding or use of mounting hardware.

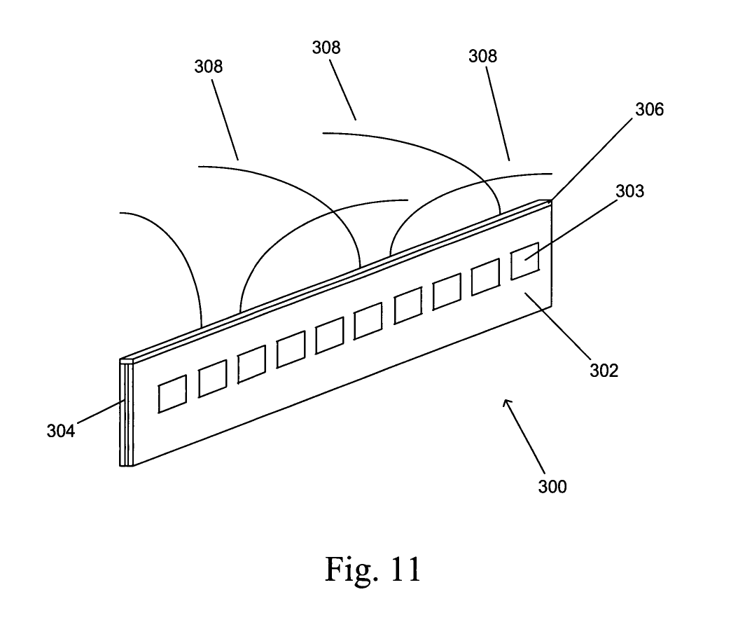

In other embodiments, any of a variety of techniques can be used to draw heat away from edge plating or a heat spreader. In many embodiments, liquid cooling is used to transport heat away from edge plating or heat spreader. In other embodiments, heat can be transported away from edge plating or a heat spreader using thermally conductive paths. An embodiment of a printed wiring board assembly including an edge plated printed wiring board connected to thermally conductive paths is shown in FIG. 11. The printed wiring board assembly 300 includes a printed wiring board 302 on which electronic devices are mounted and that includes a thermal plane 304 and edge plating 306. Thermal paths 308 connect to the edge plating 306.

In one embodiment, the thermal paths are metal wires and/or strips that are connected to the edge plating. In many embodiments, copper wires are used. In other embodiments, any thermally conductive material can be connected to the edge plating 306 to create a thermal path. In several embodiments, the thermal paths are connected to a heat sink or spreader such as a device chassis.

Although the foregoing embodiments are disclosed as typical, it would be understood that additional variations, substitutions and modifications can be made to the system, as disclosed, without departing from the scope of the invention. For example, any variety of semiconductor die configurations can be used in printed wiring board assemblies in accordance with the present invention. In addition, any variety of different die stacking, printed wiring board, heat spreader, heat sink, microfin and/or thermal path configurations can be used that utilize edge plating to transfer heat between thermally conductive planes in a printed wiring board and other elements in the assembly. Accordingly, the scope of the invention should be determined not by the embodiments illustrated, but by the appended claims and their equivalents.

What is claimed is:

1. A printed wiring board, comprising:
at least one circuit layer;
at least one dielectric layer;
at least one thermally conductive plane; and
edge plating that contacts the at least one thermally conductive plane.

2. The printed wiring board of claim 1, wherein at least one of the thermally conductive planes is constructed from carbon fiber impregnated with resin.

3. The printed wiring board of claim 2, wherein the carbon fiber is woven.

4. The printed wiring board of claim 3, wherein the carbon fiber weave is balanced.

5. The printed wiring board of claim 3, wherein the carbon fiber weave is unbalanced.

6. The printed wiring board of claim 2, wherein the carbon fibers form a mat.

7. The printed wiring board of claim 2, wherein the carbon fiber is unidirectional.

8. The printed wiring board of claim 1, wherein at least one of the thermally conductive planes includes fibrous material coated in metal.

9. The printed wiring board of claim 8, wherein the fibrous material includes Carbon, Graphite, E-glass, S-glass, Aramid, Kevlar or Quartz.

10. The printed wiring board of claim 1, wherein at least one of the thermally conductive planes includes a substrate impregnated with resin.

11. The printed wiring board of claim 10, wherein the resin is an Epoxy based resin.

12. The printed wiring board of claim 10, wherein the resin includes at least one filler to improve the thermal conductivity of the thermal plane.

13. The printed wiring board of claim 12, wherein the filler is Pyrolytic Carbon powder, Carbon powder, Carbon particles, Diamond powder, Boron Nitride, Aluminum Oxide, Ceramic particles or Phenolic particles.

14. The printed wiring board of claim 1, wherein at least one of the thermally conductive planes includes a Carbon plate.

15. The printed wiring board of claim 1, wherein at least on of the thermally conductive planes includes Carbon-Silicon Carbide (C—SiC), a metal matrix composite, a metal or Boron Nitride.

16. The printed wiring board of claim 1, wherein at least one of the thermally conductive planes possesses an in plane thermal conductivity of greater than 3 W/m.K.

17. The printed wiring board of claim 16, wherein at least one of the thermally conductive planes possesses an in plane thermal conductivity is greater than 50 W/m.K.

18. The printed wiring board of claim 17, wherein at least one of the thermally conductive planes possesses an in plane thermal conductivity is greater than 300 W/m.K

19. A printed wiring board assembly, comprising:
a printed wiring board including at least one thermally conductive plane;
an electronic device mounted on the printed wiring board; and
edge plating that contacts at least one of the thermally conductive planes.

20. The printed wiring board assembly of claim 19, further comprising a heat spreader mounted to the printed wiring board.

21. The printed wiring board assembly of claim 20, wherein the heat spreader includes microfins.

22. The printed wiring board assembly of claim 20, wherein the edge plating contacts the heat spreader.

23. The printed wiring board assembly of claim 20, wherein the electronic device contacts the heat spreader.

24. The printed wiring board assembly of claim 20, wherein the edge plating is connected to the heat spreader via a thermal interface material.

25. The printed wiring board assembly of claim 20, wherein the electronic device is connected to the heat spreader via a thermal interface material.

26. The printed wiring board assembly of claim 19, further comprising a heat sink that contacts the edge plating.

27. The printed wiring board assembly of claim 19, further comprising a heat sink that is connected to the edge plating by at least thermal interface material.

28. The printed wiring board assembly of claim 19, further comprising a heat sink that is connected to the edge plating by at least a heat spreader.

29. The printed wiring board assembly of claim 19, further comprising thermally conductive paths connected to the edge plating.

30. The printed wiring board assembly of claim 29, wherein the thermally conductive paths include Copper.

31. The printed wiring board assembly of claim 29, wherein the thermally conductive paths are wires and one end of each of the wires is connected to the edge plating.

32. The printed wiring board assembly of claim 29, wherein the thermally conductive paths are strips and one end of each of the strips is connected to the edge plating.

33. The printed wiring board assembly of claim 19, further comprising:
a second printed wiring board including a thermally conductive plane and edge plating; and
a heat sink;
wherein the edge plating of both the first and second printed wiring boards contact the heat sink.

34. The printed wiring board assembly of claim 19, further comprising:
a second printed wiring board including a thermally conductive plane and edge plating; and
a heat sink;
wherein a heat spreader is mounted to each of the printed wiring boards; and
wherein the edge plating of both the first and second printed wiring boards contacts the heat sink via the heat spreaders.

35. The printed wiring board assembly of claim 19, wherein the electronic devices are dies directly mounted on the printed wiring board.

36. The printed wiring board assembly of claim 19, wherein the electronic devices are dies connected to the printed wiring board as at least one die stack.

37. A method of constructing a printed wiring board comprising:
constructing a printed wiring board including at least one thermally conductive plane;
prefabricating the edge of the printed wiring board in preparation for edge plating;
plating thermally conductive edge plating onto the printed wiring board;
finishing the outer layers of the printed wiring board; and
mounting electronic devices on the printed wiring board.
